(19) United States
(12) Patent Application Publication
(10) Pub. No.: US 2006/0090855 A1
(43) Pub. Date: May 4, 2006

(54) Substrate mounting table, substrate processing apparatus and substrate temperature control method

(75) Inventor: Hidetoshi Kimura, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/259,037

(22) Filed: Oct. 27, 2005

Related U.S. Application Data
(60) Provisional application No. 60/689,523, filed on Jun. 13, 2005.
(60) Provisional application No. 60/635,943, filed on Dec. 15, 2004.

(30) Foreign Application Priority Data
Oct. 29, 2004 (JP) 2004-316604
May 24, 2005 (JP) 2005-151025

(51) Int. Cl. C23F 1/00; C23C 16/00

(52) U.S. Cl. 156/345.52; 118/724

(57) ABSTRACT

A substrate mounting table for mounting a substrate in a substrate processing apparatus includes a mounting table main body, an annular peripheral protrusion portion which is formed such that when the substrate is loaded on a reference surface at a substrate mounting side of the mounting table main body, it is in contact with a peripheral portion of the substrate and a sealed space filled with a heat transfer gas is formed below the substrate, a plurality of first protrusions which are formed on the reference surface inward from the annular peripheral protrusion portion such that they are in contact with the substrate when the substrate is loaded on the substrate mounting table, and a number of second protrusions which are provided independently of the first protrusions on the reference surface inward from the annular peripheral protrusion portion such that they are close to the substrate without contacting it when the substrate is loaded on the substrate mounting table.

### CROSS-REFERENCE TO RELATED APPLICATIONS:

This document claims priority to Japanese Patent Application Nos. 2004-316604 filed Oct. 29, 2004 and 2005-151025 filed May 24, 2005 and U.S. Provisional Application Nos. 60/635,943, filed Dec. 15, 2004 and 60/689,523, filed Jun. 13, 2005, the entire content of which are hereby incorporated by reference.

### FIELD OF THE INVENTION

The present invention relates to a substrate mounting table for mounting a substrate such as a semiconductor wafer thereon, a substrate processing apparatus for performing a predetermined processing, e.g., a drying etching, on the substrate loaded on the substrate mounting table, and a method for controlling the temperature of the substrate on the substrate mounting table.

### BACKGROUND OF THE INVENTION

In a manufacturing process of, e.g., semiconductor devices, plasma processing such as dry etching, sputtering or CVD (chemical vapor deposition) is widely performed on a substrate to be processed, e.g., a semiconductor wafer.

For example, in a plasma etching processing, a mounting table for mounting a semiconductor wafer (hereinafter simply referred to as “wafer”) thereon is installed in a chamber of the apparatus, and the wafer is electrostatically attracted and held by an electrostatic chuck that forms an upper portion of the mounting table. Then, by generating a plasma of a processing gas in the chamber, a plasma etching is performed on the wafer.

During the etching process, the substrate to be processed, i.e., the wafer, needs to be maintained at a desired temperature. Accordingly, the temperature of the wafer is controlled by forming a coolant path in the mounting table and, also, varying the pressure of a heat transfer gas such as He gas that is introduced between the mounting table and a rear surface of the wafer.

As one of techniques for controlling the temperature of the wafer by using the heat transfer gas, a plurality of protrusions are provided on a surface on which the wafer is attracted, and the height of the protrusions and the pressure of the heat transfer gas are adjusted to freely control the temperature of the wafer (see, for example, Japanese Patent Laid-open Application No. 2000-317761: Reference 1).

Further, there is also known a technique for improving controllability of the temperature of the wafer by way of setting the height of the protrusions within a range from 1 μm to 10 μm and setting the total contact area of the protrusions not greater than 1% of the surface area of the mounting table (see, for example, Japanese Patent Laid-open Application No. 2001-274228: Reference 2).

However, in References 1 and 2, if the height of the protrusions is low, the heat transfer He gas is difficult to diffuse uniformly, which in turn makes it difficult to maintain temperature uniformity and responsiveness in temperature control of the wafer. If the height of the protrusions is increased to prevent this problem, on the other hand, the temperature controllability for controlling the temperature of the wafer in a wider temperature range gets deteriorated.

### SUMMARY OF THE INVENTION

It is, therefore, an object of the present invention to provide a substrate mounting table capable of providing a sufficient temperature controllability while realizing a high temperature uniformity and a high responsiveness in temperature control of the wafer; a substrate processing apparatus using the substrate mounting table; and a method for controlling the temperature of the substrate.

To achieve the object, in accordance with a first aspect of the present invention, there is provided a substrate mounting table for mounting a substrate in a substrate processing apparatus including a mounting table main body; an annular peripheral protrusion portion which is formed such that when the substrate is loaded on a reference surface at a substrate mounting side of the mounting table main body, it is in contact with a peripheral portion of the substrate and a sealed space filled with a heat transfer gas is formed below the substrate; a plurality of first protrusions which are formed on the reference surface inward from the annular peripheral protrusion portion such that they are in contact with the substrate when the substrate is loaded on the substrate mounting table; and a number of second protrusions which are provided independently of the first protrusions on the reference surface inward from the annular peripheral protrusion portion such that they are close to the substrate without contacting it when the substrate is loaded on the substrate mounting table.

In this case, a distance between the second protrusions and the mounted substrate is preferably smaller than or equal to about 5 μm. Further, both a contact area between the first protrusions and the mounted substrate and a facing area of the second protrusions facing the mounted substrate are preferably smaller than or equal to about 0.8 mm².

Further, the first and the second protrusions may have cylindrical shapes. In this case, preferably, the first and the second protrusions have diameters smaller than or equal to about 1 mm.

An area ratio of the total contact area between the first protrusions and the mounted substrate to an area of the reference surface inward from the annular peripheral protrusion portion is preferably about 0.04%-5%. In this case, preferably, the first protrusions are uniformly arranged on the reference surface inward from the annular peripheral protrusion portion.

An area ratio of the total facing area of the second protrusions facing the mounted substrate to an area of the reference surface where the second protrusions are formed is preferably greater than or equal to about 15%. In this case, it is preferable that the second protrusions are distributed on the reference surface inward from the annular peripheral protrusion portion depending on a temperature distribution of the mounted substrate.

The annular peripheral protrusion portion and the first protrusions preferably have a height of about 30 μm from the reference surface.

Preferably, the substrate mounting table further includes an inner annular protruded portion, provided on the reference surface inward from the annular peripheral protrusion portion, for dividing the sealed space into an inner portion and an outer portion by being contact with the substrate when the substrate is mounted on the substrate mounting table.

In this case, the inner annular protruded portion preferably has a double structure of a first inner annular protruded portion and a second inner annular protruded portion which installed close to each other. Further, more preferably, heat transfer gas inlet units for introducing a heat transfer gas are respectively disposed in an inner portion and an outer portion of the sealed space divided by the inner annular protruded portion, and a heat transfer gas inlet unit for introducing a heat transfer gas is further provided in a gap formed between the first inner annular protruded portion and the second inner annular protruded portion.

Preferably, the inner annular protruded portion includes a first annular wall, a second annular wall and an annular recess formed between the first and the second annular wall provided close to each other. In this case, more preferably, heat transfer gas inlet units for introducing a heat transfer gas are respectively disposed in the inner portion and the outer portion of the sealed space divided by the inner annular protruded portion, and a heat transfer gas inlet unit for introducing a heat transfer gas is further provided in the annular recess.

Further, preferably, a plurality of intermediate annular protruded portions is concentrically provided between the inner annular protruded portion and the annular peripheral protrusion portion. In this case, preferably, a heat transfer gas inlet unit for introducing a heat transfer gas is disposed in the inner portion of the sealed space confined by the inner annular protruded portion, and heat transfer gas inlet units for introducing a heat transfer gas are further provided in a number of gaps formed in a plurality of intermediate annular protruded portions concentrically provided.

Further, the mounting table main body may have an electrostatic chuck for attracting and holding the substrate by using an electrostatic force.

In accordance with a second aspect of the present invention, there is provided a substrate processing apparatus including a processing vessel, for accommodating a substrate, to be depressurized; a substrate mounting table which is provided in the processing vessel and has a configuration described above; a processing mechanism for performing a process on the substrate in the processing vessel; and a heat transfer gas supply mechanism for feeding a heat transfer gas into a sealed space formed between the substrate mounting table and the substrate.

Preferably, the substrate processing apparatus further includes a controller for controlling a pressure of the heat transfer gas which is supplied from the heat transfer gas supply mechanism.

In accordance with a third aspect of the present invention, there is provided a substrate temperature controlling method for controlling a temperature of a substrate by employing the substrate mounting table described above, wherein the temperature of the substrate is controlled by controlling a pressure of a heat transfer gas fed into a sealed space formed between the substrate mounting table and the substrate.

In this method, preferably, heat transfer gas inlet units for introducing a heat transfer gas are respectively disposed in the inner portion and the outer portion of the sealed space divided by the inner annular protruded portion, and pressures of the inner portion and the outer portion of the sealed space are independently controlled, thereby controlling the temperature of the substrate.

In this case, preferably, the inner annular protruded portion has a double structure of a first inner annular protruded portion and a second inner annular protruded portion installed close to each other, and a heat transfer gas inlet unit for introducing a heat transfer gas is further provided in a gap formed between the first inner annular protruded portion and the second inner annular protruded portion such that a pressure in the gap is controlled to be lower than those in the inner portion and the outer portion of the sealed space.

Further, preferably, the inner annular protruded portion includes a first annular wall; a second annular wall; and an annular recess formed between the first and the second annular wall provided close to each other, and a heat transfer gas inlet unit for introducing a heat transfer gas is further provided in the annular recess such that a pressure in the recess is controlled to be lower than those in the inner portion and the outer portion of the sealed space.

Further, preferably, a heat transfer gas inlet unit for introducing a heat transfer gas is disposed in the inner portion of the sealed space confined by the inner annular protruded portion to thereby control a pressure in the inner portion of the sealed space, and a plurality of intermediate annular protruded portions is concentrically provided between the inner annular protruded portion and the annular peripheral protrusion portion, and heat transfer gas inlet units for introducing a heat transfer gas are further provided in a number of gaps formed in the plurality of intermediate annular protruded portions such that pressures in a number of gaps is independently controlled to thereby control the temperature of the substrate.

In accordance with a fourth aspect of the present invention, there is provided a substrate processing apparatus including a processing vessel, for accommodating a substrate, to be depressurized; a substrate mounting table, provided in the processing vessel, for mounting the substrate thereon; a processing mechanism for performing a process on the substrate in the processing vessel; a heat transfer gas supply mechanism for feeding a heat transfer gas into a sealed space formed between the substrate mounting table and the substrate; and a controller for controlling the substrate mounting table to execute the substrate temperature controlling method described above.

In accordance with a fifth aspect of the present invention, there is provided a control program executed on a computer for controlling the substrate mounting table to perform the substrate temperature controlling method described above.

In accordance with a sixth aspect of the present invention, there is provided a computer storage medium for storing a control program executed on a computer for controlling the substrate mounting table to perform the substrate temperature controlling method described above.

In accordance with the present invention, an annular peripheral protrusion portion is formed such that when the substrate is loaded on a reference surface at a substrate mounting side of the mounting table main body, it is in contact with a peripheral portion of the substrate and a sealed space filled with a heat transfer gas is formed below the substrate. Further, a plurality of first protrusions are formed on the reference surface inward from the annular peripheral protrusion portion such that they are in contact with the substrate to support it when the substrate is loaded on the substrate mounting table. Furthermore, a number of second protrusions are provided independently of the first protrusions on the reference surface inward from the annular peripheral protrusion portion such that they are close to the substrate without contacting it when the substrate is loaded on the substrate mounting table. Therefore, when the substrate temperature is controlled by introducing the heat transfer gas such as He gas into the sealed space, since the second protrusions allows the sealed space to has a sufficient height for temperature uniformity of the substrate, it is possible to improve temperature controllability.

### BRIEF DESCRIPTION OF THE DRAWINGS

The above and other objects and features of the present invention will become apparent from the following description of preferred embodiments, given in conjunction with the accompanying drawings, in which:

FIG. 1 is a cross-sectional view of a plasma processing apparatus having a wafer mounting table in accordance with a preferred embodiment of the present invention;

FIG. 2 shows an enlarged cross-sectional view of principal parts of the wafer mounting table in accordance with the preferred embodiment of the present invention;

FIG. 3 illustrates a top view of an exemplary arrangement of first and second protrusions on the wafer mounting table in accordance with the preferred embodiment of the present invention;

FIG. 4 shows graphs representing a relationship between a gas pressure and a thermal conductivity at respective heights of a sealed space, which is obtained when He gas is supplied to the sealed space under a wafer on the wafer mounting table in accordance with the preferred embodiment of the present invention;

FIG. 5 shows a model when conducting a simulation for the uniformity of the He gas in the space;

FIG. 6 provides a simulation result using the model shown in FIG. 5;

FIG. 7 shows graphs representing a relationship between a He gas pressure and a wafer temperature, which is obtained by varying a contact area ratio of the entire first protrusions;

FIG. 8 represents a relationship between a He gas pressure and a wafer temperature, wherein respective graphs are obtained by varying a height of the entire first protrusions;

FIG. 9 offers a relationship between a He gas pressure and a wafer temperature, wherein respective graphs are obtained by varying a distance between the second protrusions and a wafer W;

FIG. 10 illustrates a relationship between an area ratio of the second protrusions and a wafer temperature, wherein respective graphs are obtained by varying an area ratio of the first protrusions;

FIG. 11 provides a relationship between an area ratio of the second protrusions and a wafer temperature difference, wherein respective graphs are obtained by varying an area ratio of the first protrusions;

FIG. 12 shows an enlarged cross-sectional view of principal parts of a wafer mounting table in accordance with another preferred embodiment of the present invention;

FIG. 13 presents a horizontal sectional view of the principal parts of the wafer mounting table in accordance with another preferred embodiment of the present invention;

FIG. 14 represents an enlarged cross-sectional view of principal parts of a wafer mounting table in accordance with another preferred embodiment of the present invention;

FIG. 15 depicts a horizontal sectional view of the principal parts of the wafer mounting table in accordance with another preferred embodiment of the present invention;

FIG. 16 is an enlarged cross-sectional view of principal parts of a wafer mounting table in accordance with still another preferred embodiment of the present invention;

FIG. 17 describes an enlarged cross-sectional view of principal parts of a wafer mounting table in accordance with still another preferred embodiment of the present invention;

FIG. 18 offers a horizontal sectional view of principal parts of a wafer mounting table in accordance with still another preferred embodiment of the present invention;

FIG. 19 shows a schematic diagram for explaining gas pressures in gaps; and

FIG. 20 provides a graph illustrating a measurement result of a wafer temperature distribution.

### DETAILED DESCRIPTION OF THE PREFERRED EMBODIMENTS

Hereinafter, a preferred embodiment of the present invention will be described with reference to the accompanying drawings.

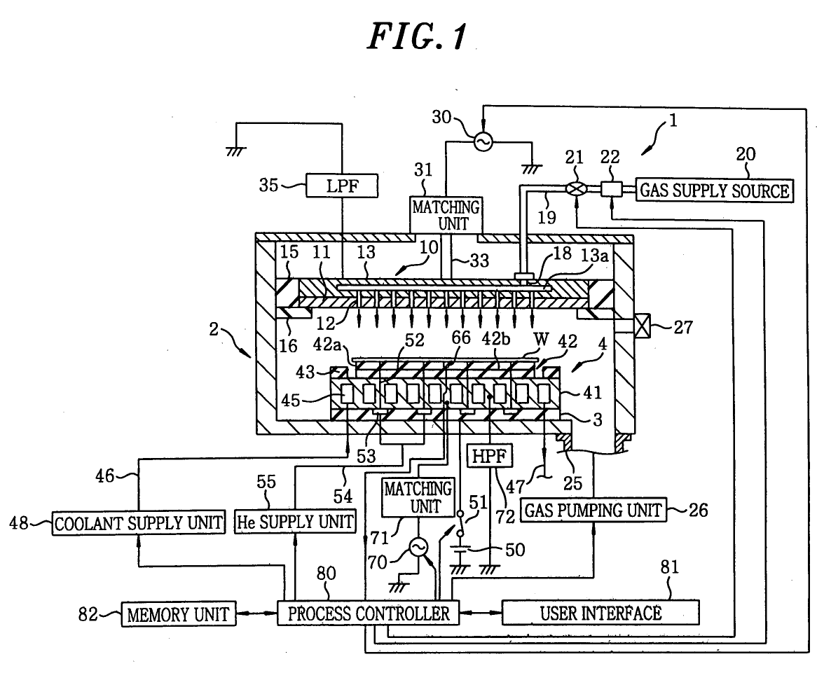

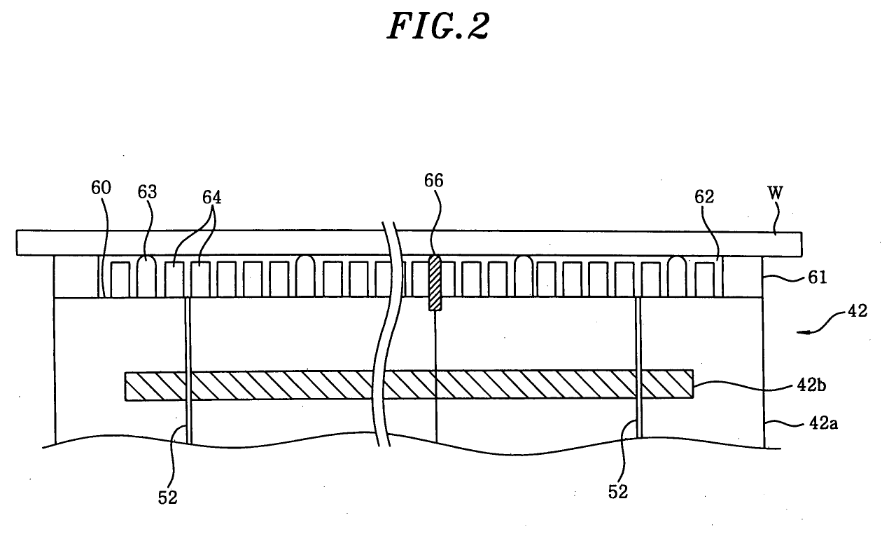

Now, there will be described a substrate mounting table in accordance with the present invention that is applied to a plasma processing apparatus. FIG. 1 is a cross sectional view of a plasma processing apparatus including a wafer mounting table in accordance with the embodiment of the present invention, and FIG. 2 sets forth an enlarged cross sectional view to show major components of the wafer mounting table.

A plasma processing apparatus 1 is configured as a parallel plate type etching apparatus in which an upper and a lower electrode plate are disposed to face each other in parallel and a capacitively coupled plasma is generated by a high frequency electric field formed between the upper and the lower electrode.

The etching apparatus 1 includes, e.g., a substantially cylindrical chamber 2 formed of aluminum whose surface is anodically oxidized. A wafer mounting table 4 for mounting thereon a substrate to be processed, i.e., a semiconductor wafer (hereinafter simply referred to as a “wafer”) W, is installed at a bottom portion of the chamber 2 via an insulation member 3 formed of, e.g., ceramic. In the preferred embodiment, the wafer mounting table 4 also functions as a lower electrode as will be described later.

A shower head 10 also serving as an upper electrode is disposed above the wafer mounting table 4 to face it in parallel. The shower head 10 has an electrode plate 11 forming a facing surface against the wafer mounting table 4; and an electrode plate support 13 that supports the electrode plate 11. The electrode plate 11 is provided with a number of gas discharge openings 12 and the electrode plate support 13 has a water-cooled structure formed of a conductive material, e.g., aluminum whose surface is anodically oxidized. Also, a gas diffusion space 13a is formed inside the electrode plate support 13.

Further, an annular insulating member 15 is interposed between the shower head 10 and the sidewall of the chamber 2 in a manner that it is attached to the sidewall of the chamber 2. Moreover, installed at a lower end of the insulating member 15 is an insulating supporting member 16 that extends inward along the circumference of the insulating member 15. The shower head 10 is supported by the supporting member 16. Also, the shower head 10 is separated from the wafer mounting table 4 by a gap of, e.g., about 10 mm to 60 mm.

The electrode plate support 13 of the shower head 10 is provided with a gas inlet port 18, which communicates with the gas diffusion space 13a and is also connected to a gas supply line 19. The other end of the gas supply line 19 is coupled to a processing gas supply source 20. A processing gas for etching is supplied to the shower head 10 from the processing gas supply source 20 via the gas supply line 19 and, then, discharged onto the wafer W through the gas diffusion space 13a of the electrode plate support 13 and the gas discharge openings 12. Further, a valve 21 and a mass flow controller 22 are installed in the gas supply line 19.

Various gases that are used conventionally can be employed as the processing gas. For example, a gas containing a halogen element such as fluorocarbon gas (CₓF_{y}) and hydrofluorocarbon gas (CₚH_{q}Fᵣ) can be utilized appropriately. In addition, it is also preferable to add N₂, O₂ gas and/or an inert gas such as Ar, He to the halogen-based gas.

Furthermore, a gas outlet line 25 is connected to a bottom portion of the chamber 2 and a gas pumping unit 26 is coupled to the gas outlet line 25. The gas pumping unit 26 has a vacuum pump such as a turbo molecular pump and is configured to evacuate the chamber 2 to vacuum, so that the chamber 2 can be depressurized to a preset vacuum level, e.g., 1 Pa or less. Further, a gate valve 27 is installed at a sidewall of the chamber 2, and the wafer W is transferred between the chamber 2 and an adjacent load lock chamber (not shown) while the gate valve 27 is open.

A first high frequency power supply 30 is connected to the shower head 10 via a matching unit 31, and a high frequency power is supplied to the shower head 10 via a power feed rod 33 connected to a central portion of the upper surface of the electrode plate support 13. Further, a low pass filter (LPF) 35 is coupled to the shower head 10. By supplying a high frequency power from the first high frequency power supply 30, a high frequency electric field is formed between the shower head 10 serving as the upper electrode and the wafer mounting table 4 serving as the lower electrode, whereby a plasma of the processing gas is generated therebetween. The first high frequency power supply 30 has a frequency not smaller than, e.g., 27 MHz. Specifically, it provides a high frequency power of a frequency of 60 MHz. By applying the relatively high frequency power, a high-density plasma in a desired dissociation state can be generated in the chamber 2, which makes it possible to execute a plasma processing under a low pressure.

The wafer mounting table 4 in accordance with the preferred embodiment of the present invention has a substantially cylindrical shape, and includes an electrode plate 41 formed of a metal and provided on the insulation member 3; and an electrostatic chuck 42 mounted on the electrode plate 41. The electrostatic chuck 42 has a diameter smaller than that of the electrode plate 41, and a focus ring 43 is disposed on the peripheral portion of the top surface of the electrode plate 41 to surround the electrostatic chuck 42. The focus ring 43 is formed of, e.g., an insulating material and by the presence of the focus ring 43, the uniformity of the etching can be improved.

A coolant circulation path 45 is formed in the electrode plate 41, and a coolant introducing line 46 and a coolant discharge line 47 are connected to the coolant circulation path 45. A coolant, e.g., a fluorine-based nonreactive liquid is supplied into the coolant circulation path 45 from a coolant supply unit 48 via the coolant introducing line 46 and circulates therein to facilitate a heat transfer between the wafer W and the coolant, whereby the wafer W is maintained at a desired temperature. Though a lower temperature coolant has a higher cooling capacity, the temperature of the coolant is preferably set to be about 20° C., because it may cause condensation when its temperature is excessively low. In a simulation to be described later, the coolant whose temperature is set to be 20° C. is used.

The electrostatic chuck 42 is designed to have a diameter slightly smaller than that of the wafer W, and has a main body 42a formed of an insulating material and an electrode 42b embedded therein. The electrode 42b is connected to a DC power supply 50. By applying a DC voltage of, e.g., 1.5 kV to the electrode 42b from the DC power supply 50, the wafer W loaded on the electrostatic chuck 42 is attracted and held by the electrostatic chuck 42 by the help of an electrostatic force, e.g., a Coulomb force or Johnsen-Rahbeck force. The DC power supply 50 is turned on or off by a switch 51. The insulating material for forming the main body 42a is, for example, ceramic such as Al₂O₃, Zr₂O₃, Si₃N₄, Y₂O₃ or the like.

A plurality of gas channels 52 for supplying a heat transfer He gas are configured to lead to the rear surface of the wafer W loaded on the wafer mounting table 4. The gas channels 52 are extended from annular recesses 53 formed in the top surface of the insulation member 3, and a He supply unit 55 for supplying the heat transfer He gas is connected to the annular recesses 53 via a gas supply line 54. The He gas is temporarily stored in the annular recesses 53 after being supplied from the He supply unit 55 via the gas supply line 54, and then is supplied to the rear surface of the wafer W via the gas channels 52. Accordingly, a heat transfer can be carried out between the coolant and the wafer W by the He gas, thereby controlling the temperature of the wafer W.

In the electrostatic chuck 42 forming an upper portion of the wafer mounting table 4, as shown in FIG. 2, when letting the top surface of the insulating main body 42a on which the wafer is loaded be a reference surface 60, an annular peripheral protrusion portion 61 is formed along the periphery of the reference surface 60. The annular peripheral protrusion portion 61 is formed such that it contacts the periphery of the wafer W when the wafer W is loaded on the wafer mounting table 4. By the presence of the annular peripheral protrusion portion 61, a sealed space 62 filled with the heat transfer He gas is formed below the wafer W when the wafer W is loaded on the wafer mounting table 4. Further, on the reference surface 60 inward from the annular peripheral protrusion portion 61, a plurality of first protrusions 63 is formed such that they get in contact with the wafer W to support it when the wafer is loaded on the wafer mounting table 4. Moreover, independently of the first protrusions 63 on the reference surface 60 inward from the annular peripheral protrusion portion 61, a number of second protrusions 64 are formed such that they are close to the wafer W without contacting it when the wafer is loaded on the wafer mounting table 4. The heat transfer He gas is supplied into the sealed space 62 via the gas channels 52 as described above.

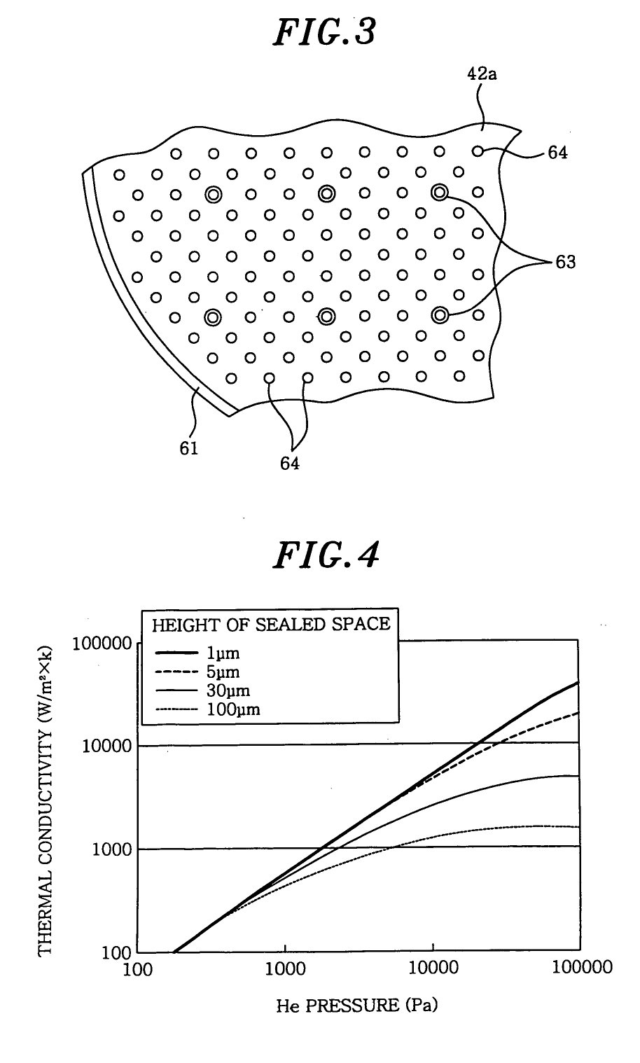

FIG. 3 illustrates an exemplary arrangement of the first and the second protrusions 63 and 64. As shown in the figure, the first protrusions 63 and the second protrusions 64 have cylindrical shapes. The first protrusions 63 are equi-spaced and the second protrusions 64 are also arranged at a same interval between the first protrusions 63.

A thermocouple 66 is buried in the top surface of the electrostatic chuck 42 so that it detects the temperature of the wafer W. Then, based on the detection result, the pressure of the He gas in the sealed space 62 is controlled as will be described later.

A second high frequency power supply 70 is connected to the electrode plate 41 of the wafer mounting table 4 serving as the lower electrode, and a matching unit 71 is installed on a feeder line thereof. The second high frequency power supply 70 has a frequency ranging from, e.g., 100 kHz to 13.56 MHz, specifically, 2 MHz. By applying such a high frequency power, proper ion action can be imposed on the wafer W without causing a damage thereon.

Each component of the plasma processing apparatus 1 is connected to and controlled by a process controller 80. Specifically, the process controller 80 controls the coolant supply unit 48, the He supply unit 55, the gas pumping unit 26, the switch 51 of the DC power supply 50 for the electrostatic chuck 42, the valve 21, the mass flow controller 22, and so forth. In particular, as for the He supply unit 55, the process controller 80 transmits a control signal to the He supply unit 55 based on the detection result from the thermocouple 66 serving as a temperature sensor, to thereby control the pressure of the He gas in the sealed space 62, such that the wafer W is maintained at a desired temperature. Further, a high pass filter 72 is connected to the electrode plate 41.

Moreover, a user interface 81 for allowing a process manager to operate the plasma processing apparatus 1 is connected to the process controller 80, wherein the user interface 81 includes a keyboard for inputting a command, a display for showing an operational status of the plasma processing apparatus 1, and the like.

Moreover, also connected to the process controller 80 is a memory unit 82 for storing therein a recipe including a control program, processing condition data and the like to be used in realizing various processings performed in the plasma processing apparatus 1 under the control of the process controller 80.

Further, when a command is received from the user interface 81, a necessary recipe is retrieved from the memory unit 82 to be executed by the process controller 80, whereby a desired processing is performed in the plasma processing apparatus 1 under the control of the process controller 80. Moreover, the necessary recipe to be used can be retrieved from a readable storage medium such as a CD-ROM, a hard disk, a flexible disk, a flash memory or the like, or retrieved through an on-line connected via, for example, a dedicated line to another apparatus available all the time.

Hereinafter, an operation of the plasma processing apparatus 1 configured as described above will be explained.

First, the gate valve 27 is opened and then a substrate to be processed, i.e., a wafer W, is carried into the chamber 2 from a load lock chamber (not shown) to be mounted on the electrostatic chuck 42 of the wafer mounting table 4. Then, the gate valve 27 is closed and the chamber 2 is evacuated to a predetermined vacuum level by the gas pumping unit 26.

Thereafter, the valve 21 is opened, and a processing gas is supplied into the gas diffusion space 13a inside the shower head 10 from the processing gas supply source 20 via the gas supply line 19 and the gas inlet port 18 while its flow rate is controlled by the mass flow controller 22. The processing gas is discharged uniformly towards the wafer W through the gas discharge openings 12 of the electrode plate 11, as indicated by arrows in FIG. 1, so that the internal pressure of the chamber 2 can be maintained at a preset level.

At that time, a high frequency power of a frequency not smaller than 27 MHz, e.g., 60 MHz, is applied to the shower head 10 serving as the upper electrode from the first high frequency power supply 30. As a result, a high frequency electric field is formed between the shower head 10 serving as the upper electrode and the wafer mounting table 4 serving as the lower electrode, whereby the processing gas is dissociated and converted into a plasma so that the wafer W is etched by the plasma. While the plasma is generated, a DC voltage is concurrently applied to the electrode 42b of the electrostatic chuck 42 from the DC power supply 50 so that the wafer W is electrostatically attracted and held on the electrostatic chuck 42. At this time, the wafer W is attracted to the annular peripheral protrusion portion 61 formed on the reference surface of the insulating main body 42a and, at the same time, supported by the first protrusions 63, thus forming a sealed space below the wafer W.

Meanwhile, a high frequency power of a frequency ranging from 100 kHz to 13.56 MHz, e.g., 2 MHz, is applied to the wafer mounting table 4 serving as the lower electrode from the second high frequency power supply 70. Resultantly, ions among the plasma are attracted toward the wafer mounting table 4, so that etching anisotropy is improved by ion assist.

To perform a high-precision etching by using the plasma, the temperature of the wafer W needs to be controlled with a high precision. Accordingly, the heat transfer He gas is supplied into the sealed space 62 below the wafer W while controlling its pressure at a predetermined level, whereby the wafer W can be maintained at a desired temperature.

Conventionally, only a wafer supporting member corresponding to the first protrusions 63 has been installed in the sealed space 62 which is confined by the annular peripheral protrusions portion 61.

FIG. 4 shows a relationship between the gas pressure and the thermal conductivity when the He gas serving as a heat transfer gas is supplied into the sealed space. FIG. 4 is obtained by conducting a simulation based on actual measurement data by a DSCM (Direct Simulation Monte Carlo) method, using “Modeling of Rarefied Gas Heat Conduction Between Wafer and Susceptor” which is disclosed in IEEE TRANSACTIONS ON SEMICONDUCTOR MANUFACTURING (February 1998, VOL. 11, NO. 1, p. 25 to 29; K. Denpoh). As shown in FIG. 4, the thermal conductivity increases in proportion to the gas pressure regardless of the height (distance) of the sealed space in a lower pressure range. However, in a higher pressure range, the thermal conductivity tends to be saturated if the height of the sealed space is high, even though the gas pressure increases. That is, for example, if the height of the sealed space is equal to or greater than 30 μm, a margin of variation in thermal conductivity, which is dependent on a variation in the gas pressure, becomes small, resulting in reduction of a controllable temperature range for the wafer W.

Thus, to improve the temperature controllability of the wafer W dependent on the variation of the gas pressure, the height of the sealed space is preferably set to be small, e.g., not higher than 5 μm.

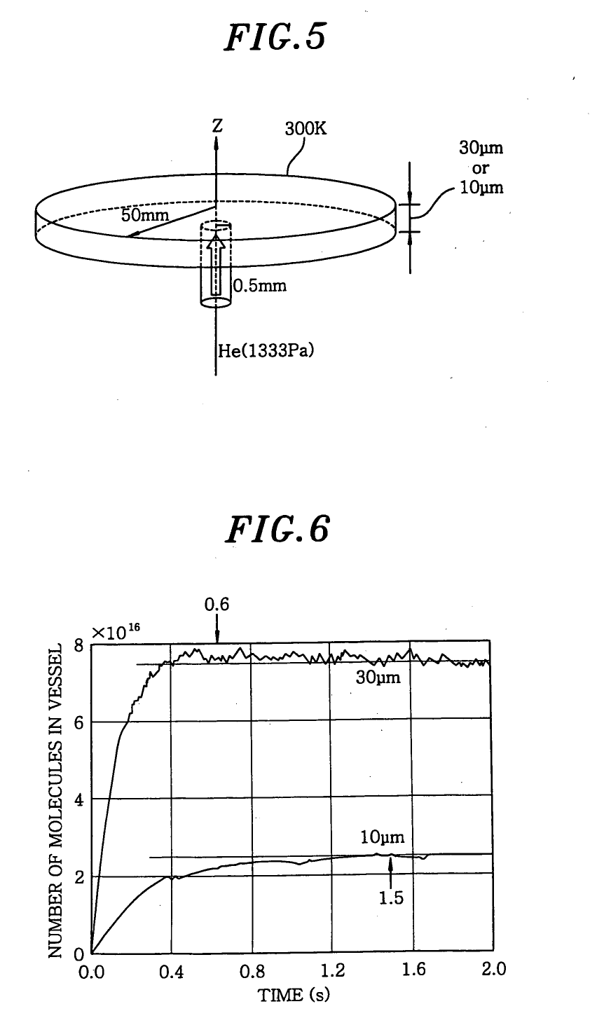

Further, referring to FIG. 5, uniformity of the He gas in the sealed space was investigated by conducting a simulation using a modeling for charging He gas of 1333 Pa into a vessel having a diameter of 50 mm and a height of 30 μm or 10 μm through a gas inlet opening with a diameter of 0.5 mm which is provided in a lower central portion of the vessel, wherein the temperature of the vessel wall was set to be 300 K. FIG. 6 shows the simulation result, and it describes a relationship between time (horizontal axis) and the number of molecules in the vessel (vertical axis). From FIG. 6, it is found that the time required until the number of molecules becomes a constant is 0.6 second when the height of the sealed vessel is 30 μm, while it is 1.5 seconds when the height is 10 μm. That is, in case the height of the sealed space is set to be low, i.e., 10 μm, resistance against the movement of the molecules is greater and efficiency for charging the molecules is poorer compared with the case when the height is 30 μm. Thus, in such a case, an unbalanced gas distribution would be easily caused to thereby deteriorate temperature uniformity and responsiveness in temperature control of the wafer.

From the above-described result, it is revealed that, in a conventional case where only a wafer supporting member corresponding to the first protrusions 63 is provided in the sealed space 62 confined by the annular peripheral protrusions portion 61, the temperature controllability deteriorates if the height of the sealed space is increased. If the height of the space is lowered, on the other hand, the gas charging efficiency deteriorates, resulting in a reduction in temperature uniformity of the wafer. Thus, conventionally, it has been difficult to obtain a high temperature controllability while maintaining a temperature uniformity of the wafer.

In comparison, in this embodiment, separately provided on the reference surface 60 inward from the annular peripheral protrusion portion 61 are a plurality of first protrusions 63 which get in contact with the wafer W to support it when the wafer is loaded on the wafer mounting table 4 and a number of second protrusions 64 which are close to the wafer W without contacting it when the wafer is loaded on the wafer mounting table 4. Since a heat transfer is effectively carried out by the second protrusions 64, the heat transfer effect in the heat transferring surface becomes equal to an effect obtained by lowering a height of the sealed space 62. Accordingly, a temperature controllability of the wafer W can be improved because a margin of variation in the thermal conductivity which is dependent on a variation in the gas pressure becomes larger and, simultaneously, a temperature uniformity of the wafer can be ensured because the height of the sealed space 62 becomes substantially large by the annular peripheral protrusion portion 61 and the first protrusions 63 and a gas distribution in the sealed space 62 becomes uniform.

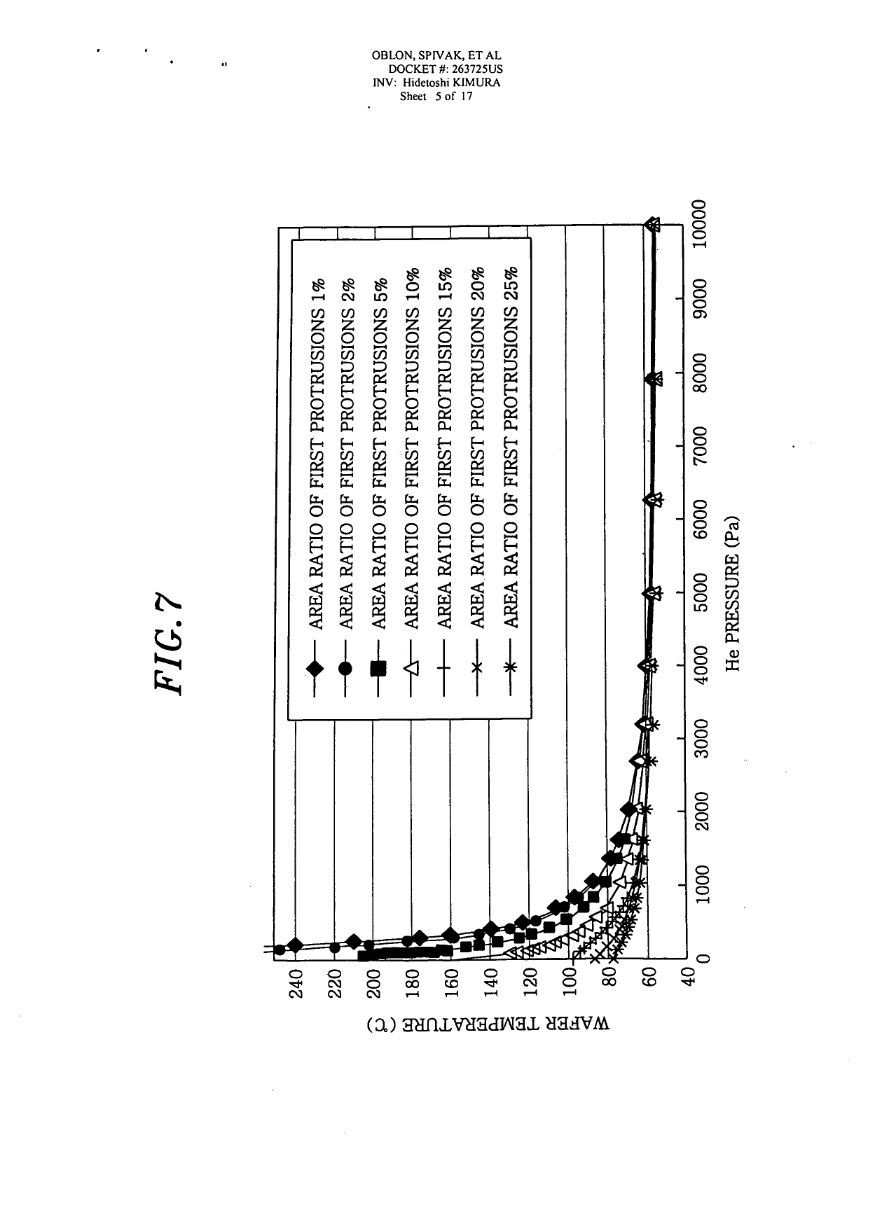

As in this embodiment, in case the temperature of the wafer W being plasma-processed (plasma-etched) is controlled by using a heat transfer He gas, the pressure of the He gas can range from 0 Pa to 6650 Pa in consideration of an adsorptive force of an electrostatic chuck. Further, for controllability of the plasma processing, the wafer temperature needs to be controlled within the range of about 50° C. to 200° C. when employing the aforementioned He gas pressure range. In this case, since the first protrusions 63 and the wafer W, i.e., solids, are in contact, more heat is transferred through the first protrusions 63 than through the He gas. Therefore, if a contact area between the first protrusions 63 and the wafer W is excessively wide, it is difficult to ensure 200° C. in the wafer temperature. FIG. 7 illustrates a relationship between the He gas pressure and the wafer temperature, which is obtained by varying a contact area ratio of the entire first protrusions 63 (a ratio of a contact area of the entire first protrusions 63 to an area of the reference surface 60 inward from the annular peripheral protrusion portion 61). FIG. 7 is obtained by conducting a simulation based on the Denpoh's method under the conditions of the mounting table diameter of 300 mm, a wafer diameter of 300 mm and a heat input of 2400 W, wherein the second protrusions 64 are not provided and the first protrusions 63 shaped as a cylinder whose diameter and height are respectively 0.5 mm and 30 μm are uniformly arranged. FIG. 7 shows that the contact area ratio of the first protrusions 63 needs to be set within the range of 2% to 5% to control a maximum temperature up to about 200° C. However, if the maximum temperature lower than 200° C. is possible, the contact area ratio can be increased. Further, if the maximum temperature of 80° C. is possible, the contact area ratio can be increased up to 25%.

The lowest limit of the contact area of the first protrusions 63 can be set regardless of the temperature control. Supposing the first protrusions 63 having a diameter of 0.5 mm are arranged uniformly, it is sufficient if the wafer W is contact with the first protrusions 63 with a uniform pressure at a maximum bent amount of 3 μm at the pressure of 16630 Pa. Therefore, when considering a height manufacturing accuracy of ±2.5 μm, a gap between the first protrusions 63 should be 21.2 mm, resulting in a contact area of 0.04%. Thus, the contact area of the first protrusions 63 is preferably 0.04%.

In this case, it is preferable to install the first protrusions 63 uniformly on the reference surface 60 inward from the annular peripheral protrusion portion 61.

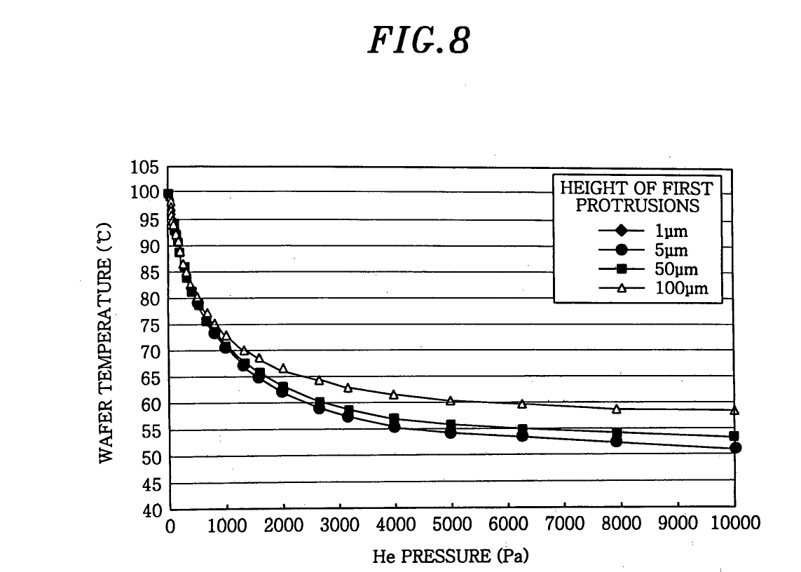

In order to decrease the wafer temperature, the He gas pressure needs to be increased. Further, in order to obtain the minimum temperature of about 50° C. at the He gas pressure of 6650 Pa, there is a need to properly set a height of the sealed space 62, i.e., a height of the first protrusions 63. FIG. 8 offers a relationship between a He gas pressure and a wafer temperature, which is obtained by varying the height of the first protrusions 63. FIG. 8 is obtained by conducting a simulation by using the same method under the same conditions as in FIG. 7. Referring to FIG. 8, if the height of the first protrusions 63 (i.e., the height of the sealed space 62) is higher than or equal to 50 μm, it is difficult to reduce the wafer temperature down to around 50° C. at the He pressure of 6650 Pa. Thus, it is difficult to control the temperature at around 50° C. with accuracy. Meanwhile, if the height of the first protrusions 63 is lower than or equal to 5 μm, as described above, efficiency for charging the He gas is poorer, thereby deteriorating temperature uniformity and responsiveness in temperature control of the wafer. Therefore, it is concluded that the height of the first protrusions 63 is properly set to be about 30 μm.

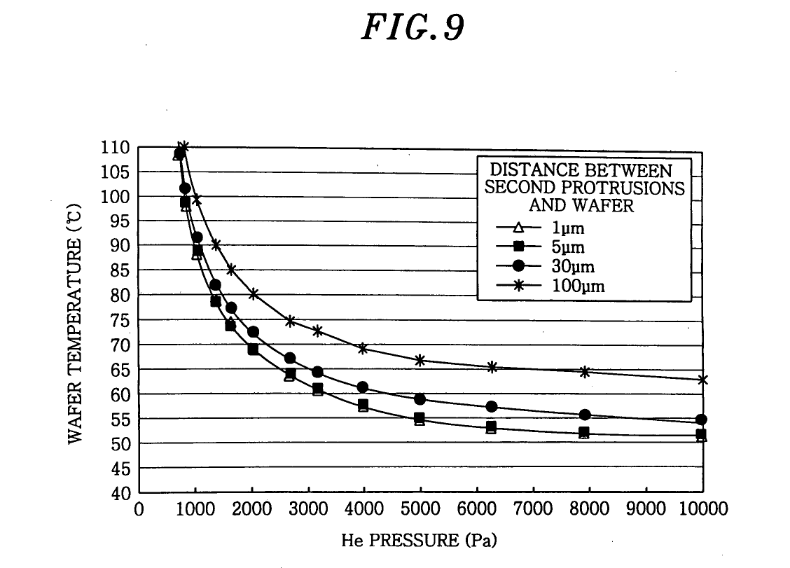

It is preferable to properly set a distance between the second protrusions 64 and the wafer W because it has an effect on the thermal conductivity of He gas. FIG. 9 illustrates a relationship between a He gas pressure and a wafer temperature, which is obtained by varying the distance between the second protrusions 64 and the wafer W. FIG. 9 is obtained by conducting a simulation by using the same method under the same conditions as in FIG. 7. Referring to FIG. 9, if the distance between the second protrusions 64 and the wafer W is smaller than or equal to about 5 μm, the thermal conductivity becomes more improved and, thus, it is possible to reduce the wafer temperature down to around 50° C. at the He pressure of about 6650 Pa. Accordingly, a preferable distance between the second protrusions 64 and the wafer W is smaller than or equal to about 5 μm.

In the middle of the plasma processing, there is need to quickly change the wafer temperature. As described above, when the height of the first protrusions 63 is set to be about 30 μm and the distance between the second protrusions 64 and the wafer W is set to be smaller than or equal to about 5 μm, it is possible to increase the responsiveness to the He gas pressure variation in a space around the first and the second protrusions 63 and 64.

Moreover, for the responsiveness to the He gas pressure variation in the space around the first and the second protrusions 63 and 64, it is preferable that both a contact area between the first protrusions 63 and the wafer W and an area of the surface of the second protrusions 64 facing the wafer W are smaller than or equal to about 0.8 mm² (or, diameters of the first and the second protrusions 63 and 64 are smaller than or equal to a thickness of the wafer). By doing this, a delay of response to He gas pressure variation hardly occurs. Further, since a heat transfer distance of a horizontal direction is approximately equal to a heat transfer distance of a thickness direction in a wafer's portion corresponding to the first and the second protrusions 63 and 64, a temperature nonuniformity hardly occurs in a normal state of the temperature control.

As described above, the second protrusions 64 serves to adjust the thermal conductivity. Thus, by locally installing the second protrusions 64, at a certain spot, a temperature controllability by using the He gas can be improved and, namely, its temperature can be decreased. For example, in the plasma processing of the wafer W, wherein a temperature in a peripheral portion of the wafer W becomes higher than that in a central portion thereof, the second protrusions 64 are provided only at the peripheral portion of the wafer W or the more second protrusions 64 are provided in the peripheral portion than in other portions. Accordingly, the temperature in the peripheral portion of the wafer W can be reduced. In other words, the second protrusions 64 are installed depending on a temperature distribution of the wafer W, whereby the uniformity of the wafer temperature can be further improved.

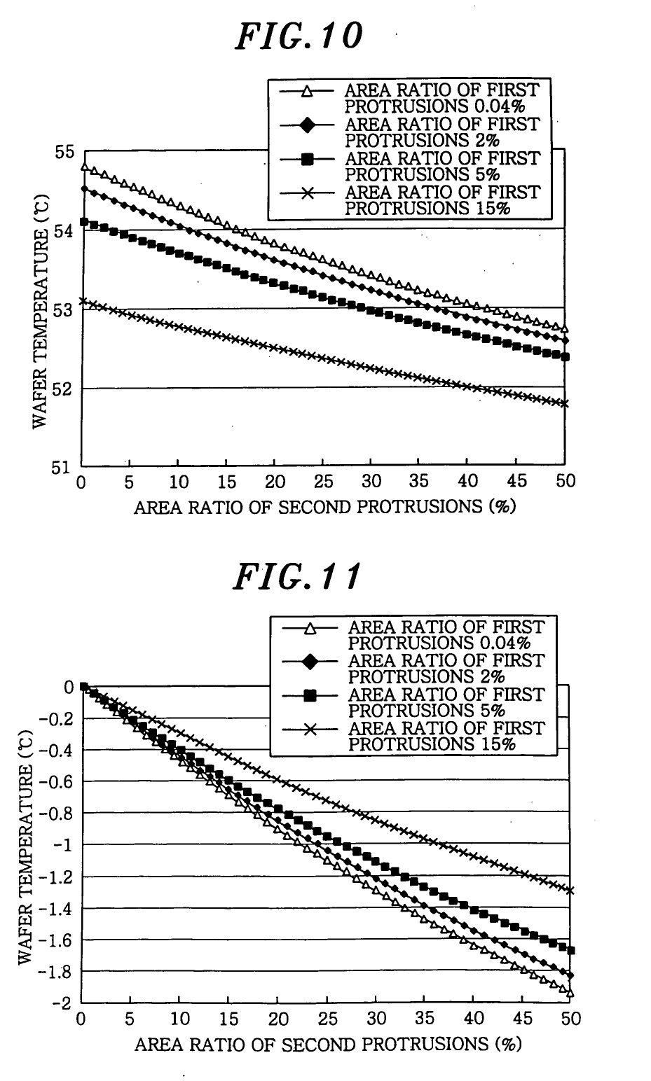

An area ratio of the second protrusions 64 directly affects the temperature controllability of the wafer. FIGS. 10 and 11 illustrates a relationship between the area ratio of the second protrusions and the wafer temperature and a relationship between the area ratio of the second protrusions and a wafer temperature difference, respectively, by varying an area ratio of the first protrusions. FIGS. 10 and 11 are obtained by conducting a simulation as in FIG. 7 while setting a height of the first protrusions 63 at 30 μm and a distance between the second protrusions 64 and the wafer W at 5 μm. As shown in FIG. 10, the smaller the area ratio of the first protrusions 63 gets, the higher the wafer temperature becomes. However, as illustrated in FIG. 11, as the area ratio of the first protrusions 63 is smaller, the wafer temperature difference, i.e., the temperature controllability by presence of the second protrusions 64 is more improved. Moreover, when the area ratio of the first protrusions 63 is within a preferable range of 2% to 5% and the area ratio of the second protrusions 64 is about 15%, it is possible to obtain a comparatively high temperature controllability having a temperature difference ranging from −0.6° C. to −0.7° C. Accordingly, the area ratio of the second protrusions 64 is preferably greater than or equal to about 15%. Further, in case the area ratio is about 20%, the temperature difference ranges from −0.8° C. to −1.0° C. Thus, it is more preferable that the area ratio is greater than or equal to 20%. As the area ratio of the second protrusions 64 increases, the temperature controllability increases. But, if the second protrusions 64 are uniformly arranged in the same size and shape, an upper limit of the area ratio becomes 25% for, e.g., manufacturability. However, the area ratio can be increased by nonuniformly arranging the second protrusions 64 or by devising the manufacturing process.

Further, it is preferable that the first and the second protrusions 63 and 64 have cylindrical shapes and diameters smaller than or equal to about 1 mm in terms of the manufacturability, the temperature controllability or the like.

Hereinafter, another preferred embodiment of the present invention will be described.

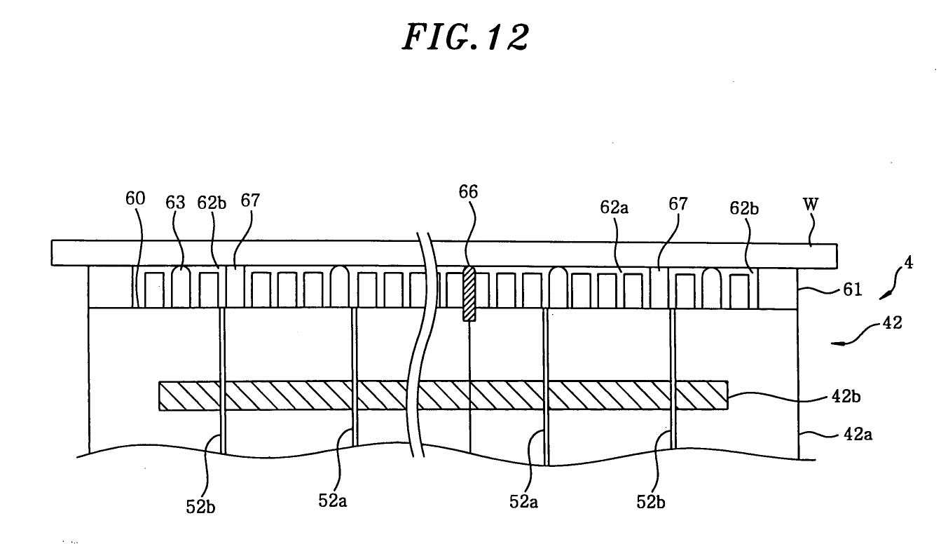

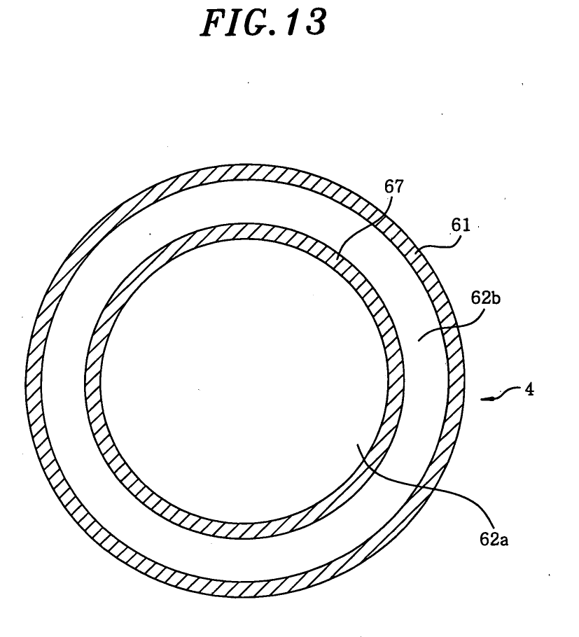

FIG. 12 shows an enlarged cross sectional view of principal parts of a wafer mounting table in accordance with another preferred embodiment of the present invention, and FIG. 13 presents a horizontal sectional view thereof. In this embodiment, installed on the reference surface 60 inward from the annular peripheral protrusion portion 61 is an inner annular protruded portion 67, which is contact with the wafer W and divides the sealed space 62 into an inner portion 62a and an outer portion 62b when the wafer W is mounted on the wafer mounting table. Further, gas channels 52a and 52b are respectively connected to the inner and the outer portion 62a and 62b, thereby independently controlling the He gas pressure. FIG. 13 explains the arrangement of the annular peripheral protrusion portion 61 and the inner annular protruded portion 67, wherein other members are omitted.

By dividing the sealed space 62 into the inner and the outer portion 62a and 62b and separately controlling the He gas pressure thereof, it is possible to separately control the temperature of the peripheral portion of the wafer W where the temperature easily increases during the plasma processing and that of other portions. Thus, it is possible to improve the uniformity of the wafer temperature. Specifically, by increasing the pressure of the outer portion 62b, the thermal conductivity is improved and the peripheral portion of the wafer W is further cooled, so that the uniformity of the wafer temperature can be enhanced. Since a basic composition of the embodiment in FIG. 12 is identical to that of the embodiment illustrated in FIG. 2, like reference numerals are given therefor and a description thereof is omitted.

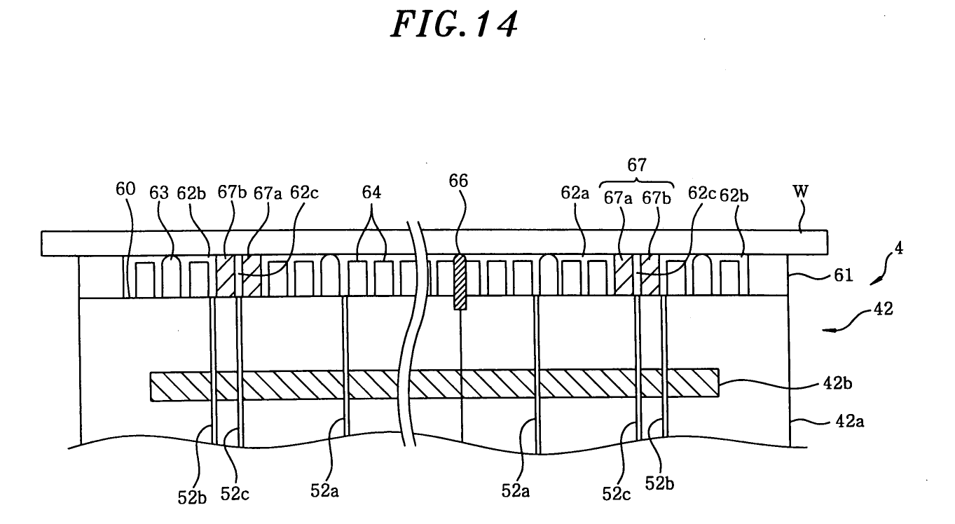

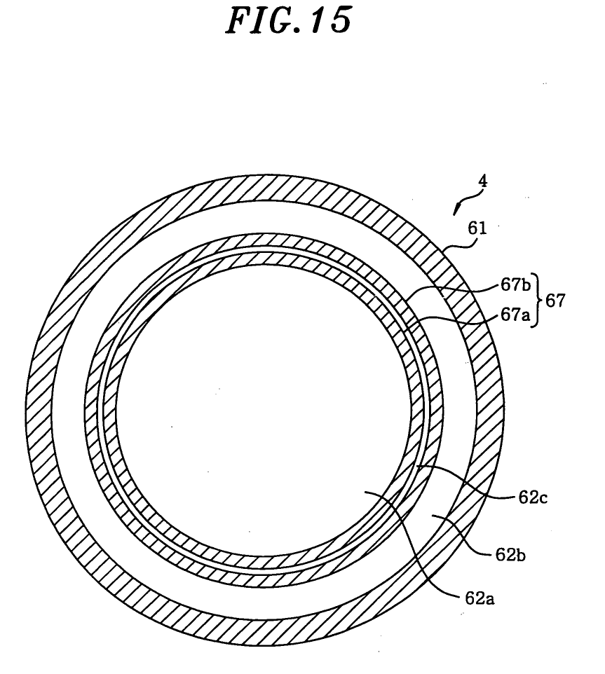

FIGS. 14 and 15 represent a modified example of the wafer mounting table in accordance with the embodiment of FIG. 12. FIG. 14 represents an enlarged cross-sectional view of principal parts of the wafer mounting table in accordance with this embodiment, and FIG. 15 depicts a horizontal sectional view thereof. In this embodiment, the inner annular protruded portion 67 for dividing the sealed space 62 into an inner portion 62a and an outer portion 62b has a double structure, so that a gas can be introduced into a third sealed space (gap 62c) formed therebetween.

The inner annular protruded portion 67 is formed of a first inner annular protruded portion 67a and a second inner annular protruded portion 67b which is outward from and close to it. The first and the second inner annular protruded portion 67a and 67b have a height such that they are contact with the wafer W when the wafer W is mounted. Further, the gas channel 52c is connected to the gap 62c formed between the first inner annular protruded portion 67a and the second inner annular protruded portion 67b. Accordingly, by introducing He gas into the inner portion 62a, the outer portion 62b and the gap 62c through the gas channels 52a, 52b and 52c, respectively, the gas pressure can be controlled independently. FIG. 15 explains the arrangement of the annular peripheral protrusion portion 61 and the inner annular protruded portion 67 (the first and the second inner annular protruded portion 67a and 67b), wherein other members are omitted.

It is preferable that the gas pressure of the gap 62c is lower than that of the inner and the outer portion 62a and 62b. Generally, a diameter of the electrostatic chuck 42 is designed smaller than that of the wafer W to avoid a direct effect of a plasma, so that the wafer W is mounted with its peripheral end horizontally protruded than the electrostatic chuck 42 as illustrated in the figure. Thus, the temperature of the peripheral portion of the wafer W tends to rise easier than that of the central portion thereof. Accordingly, in the embodiment of FIG. 12, the sealed space 62 is divided into the inner and the outer portion 62a and 62b by the inner annular protruded portion 67 and, then, the gas is separately introduced thereinto through the gas channels 52a and 52b. By setting the pressure of the outer portion 62b corresponding to the peripheral portion of the wafer W higher than that of the inner portion 62a corresponding to the central portion of the wafer W, a cooling efficiency is improved, thereby achieving an in-surface uniformity of the wafer temperature.

However, in the embodiment of FIG. 12, the gas in the outer portion 62b where the gas pressure is higher may leak into the inner portion 62a after going over an uppermost portion of the inner annular protruded portion 67. If the gas enters into the inner portion 62a from the outer portion 62b after going over the inner annular protruded portion 67, the gas pressure in the inner portion 62a is changed to be unstable. Accordingly, it is difficult to uniformly control the in-surface temperature of the wafer W. Consequently, in this embodiment, the gap 62c is formed in the inner annular protruded portion 67 having a double structure, and the gas pressure in the gap 62c is set to be lower than those of the inner and the outer portion 62a and 62b. As a result, even if the gas leaks from the outer portion 62b where its gas pressure is relatively high by going over the second inner annular protruded portion 67b, it flows into the gap 62c where the gas pressure is low. Since the gap 62c serves as a buffer space, a pressure in the inner portion 62a can be prevented from being changed.

By providing the inner annular protruded portion 67 of the double structure and forming the gap 62c therebetween, it is possible to lessen the mutual effect caused by gas pressure difference in the inner portion 62a and the outer portion 62b.

Although the thickness of the first and the second inner annular protruded portion 67a and 67b are different from the width of the gap 62c in FIGS. 14 and 15, the thickness and the width can be equal or different. Further, they can be properly set depending on the gas pressures in the inner portion 62a, the outer portion 62b and the gap 62c or the like. For example, it is possible to set the thickness of the first and the second inner annular protruded portion 67a and 67b and the width of the gap 62c to be 2 mm and 1 mm, respectively. Since a basic composition of the embodiment in FIG. 14 is identical to that of the embodiment illustrated in FIG. 2, like reference numerals will be assigned therefore, and a description thereof will be omitted.

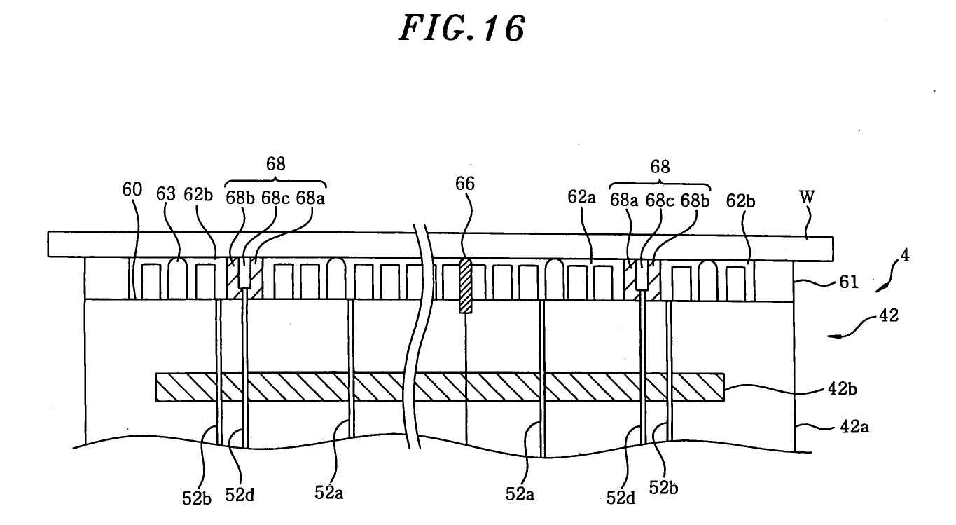

FIG. 16 represents an additional modified example of the wafer mounting table in accordance with the embodiment of FIG. 12. FIG. 16 is an enlarged cross-sectional view of the principal parts of the wafer mounting table. In this embodiment, there is provided an inner annular protruded portion 68 on which a groove is formed.

In other words, the inner annular protruded portion 68 includes an inner peripheral wall 68a; an outer peripheral wall 68b; and a recessed groove 68c formed therebetween. The inner and the outer peripheral wall 68a and 68b are annularly protruded with a height such that they are contact with the wafer W when the wafer W is mounted. Further, a gas channel 52d is connected to a bottom of the groove 68c. In this embodiment, the gas pressure in the groove 68c is set to be lower than those in the inner and the outer portion 62a and 62b, so that the mutual effect caused by different gas pressures in the inner portion 62a and the outer portion 62b can be lessened as in the embodiment in FIGS. 14 and 15.

Also in this embodiment, the thickness of the inner and the outer peripheral wall 68a and 68b and the width of the groove 68c can be same or different and can be properly set. Since a basic composition of the embodiment in FIG. 16 is identical to that of the embodiment illustrated in FIG. 2, like reference numerals are given therefore, and a description thereof is omitted.

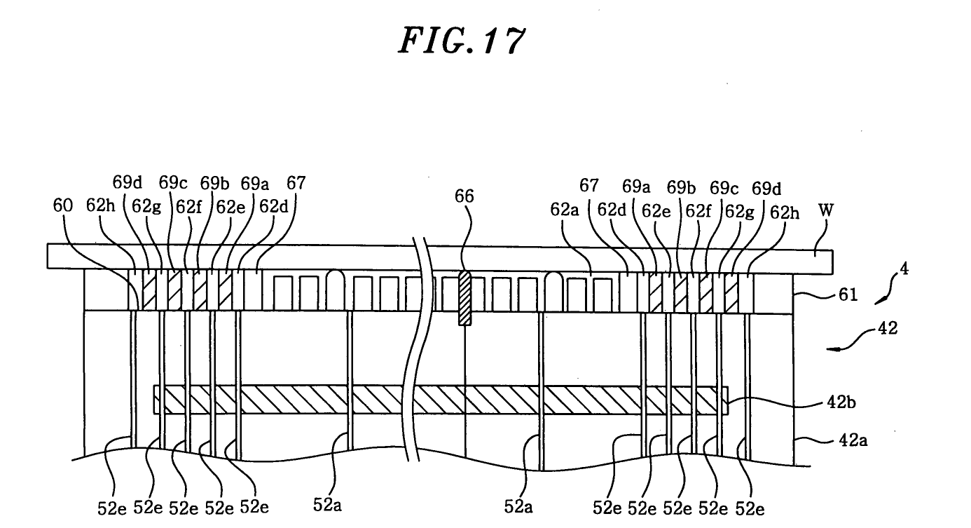

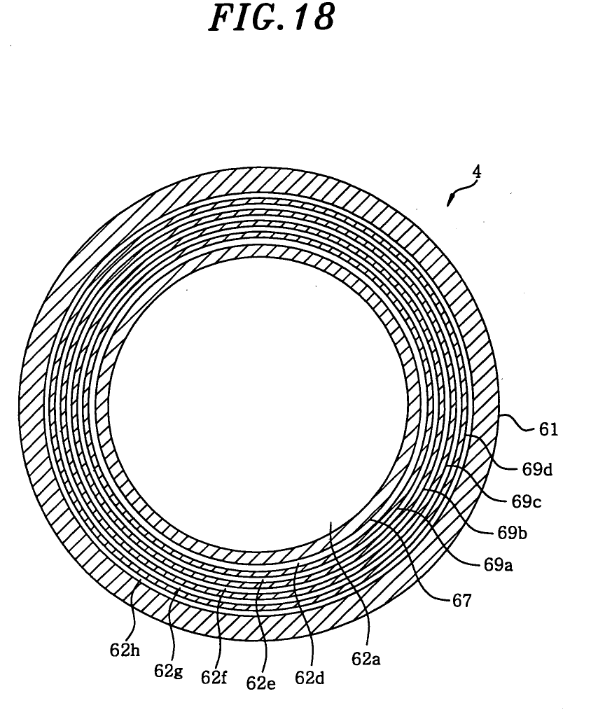

FIGS. 17 and 18 provide an additional modified example of the wafer mounting table. FIG. 17 describes an enlarged cross-sectional view of principal parts of the wafer mounting table in accordance with this embodiment, and FIG. 18 offers a horizontal sectional view thereof. In this embodiment, a plurality of intermediate annular protruded portions 69a, 69b, 69c and 69d is concentrically provided between the annular peripheral protrusion portion 61 and the inner annular protruded portion 67 with a height such that they are contact with the wafer W when the wafer W is mounted. Further, gas channels 52e for introducing He gas is connected to respective gaps 62d, 62e, 62f, 62g and 62h (five in this example) formed in the intermediate annular protruded portions 69a to 69d, so that their gas pressures can be independently controlled. With such configuration, when the gas pressure in the gap 62h is set to be high, the gas pressure in the adjacent gap 62g is set to be low. That is, the gas pressures in the gaps 62d to 62h can be alternately set to be high and low. FIG. 18 explains the arrangement of the annular peripheral protrusion portion 61, the inner annular protruded portion 67 and the intermediate annular protruded portions 69a to 69d, wherein other members are omitted.

As described above, the temperature of the peripheral portion of the wafer W may easily increase. Therefore, in the embodiment shown in FIG. 12, the gas pressure in the outer portion 62b between the inner annular protruded portion 67 and the annular peripheral protrusion portion 61 is set relatively higher than that of the inner portion 62a. Accordingly, in the outer portion 62b, the thermal conductivity is improved, thereby increasing a cooling efficiency of He gas. However, since the wafer W has the relatively high thermal conductivity itself, even if the peripheral portion thereof is only cooled, the cold heat is transferred inwardly. Considering the thermal conductivity of the wafer W itself, it is preferable to increase an in-surface uniformity of the temperature of the wafer W by more separately controlling the gas pressure.

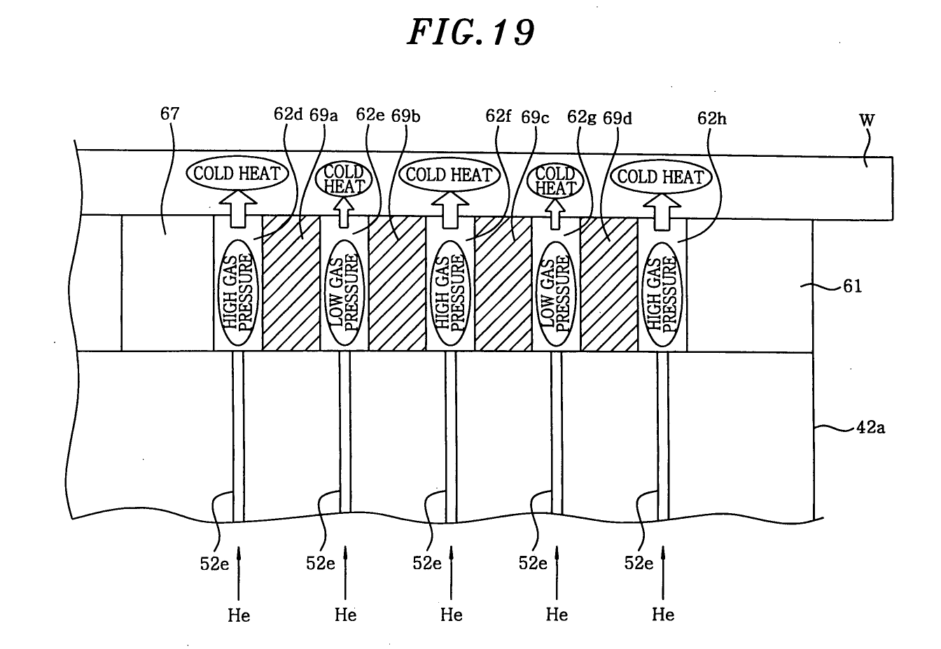

In this embodiment, with the aforementioned configuration, as depicted in FIG. 19, the gas pressure in the gap 62g adjacent to the gap 62h, where an intensive cooling is carried out due to the highest gas pressure, is relatively set to be low by considering the thermal conductivity of the wafer W, so that an excessive cooling can be avoided. On the other hand, in the gap 62f provided inward from the gap 62g, the gas pressure is set higher than that in the gap 62g to slightly strengthen the cooling. In this manner, by finely varying the gas pressures, the cooling accuracy can be enhanced. Accordingly, it is possible to precisely control the wafer temperature by using He gas. As a result, the temperature distribution on the wafer W can be controlled with high accuracy, thereby enabling to achieve the uniformity.

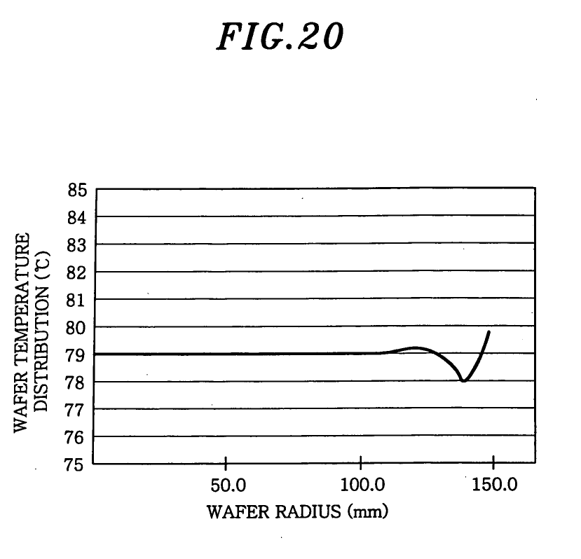

FIG. 20 shows a measurement result of the temperature distribution on the wafer W, which is obtained by heating the wafer W by using the wafer mounting table having the same configuration as that of FIG. 17. The horizontal axis of FIG. 20 indicates a distance (radius) from a center of a 300 mm wafer W which is set to be 0. Typically, a wafer W of the same size have a temperature difference of about ±5° C. However, referring to FIG. 20, the temperature distribution (difference) is restricted within ±1° C. even in the peripheral portion of the wafer W, i.e., distances ranging from about 120 mm to 150 mm. Therefore, by using the wafer mounting table of this embodiment, it is possible to ameliorate the in-surface uniformity of the wafer temperature with high accuracy.

Although the thickness of the inner and the peripheral annular protruded portion 67 and 61, the thickness of the intermediate annular protruded portions 69a to 69d and the width of the gaps 62d to 62h are different from each other in FIGS. 17 to 19, they can be same or different and further can be properly set. Further, it is possible to properly set the number of the intermediate annular protruded portions and the gaps. Since a basic composition of the embodiment in FIGS. 17 to 19 is identical to that of the embodiment illustrated in FIG. 2, like reference numerals are assigned therefore, and a description thereof is omitted.

While the invention has been shown and described with respect to the preferred embodiments, it will be understood by those skilled in the art that various changes and modification may be made without departing from the spirit and scope of the invention as defined in the following claims. For example, although the wafer mounting table having an electrostatic chuck has been employed, the electrostatic chuck is not necessary. Further, although there has been described a parallel plate plasma etching apparatus for applying a high frequency power to an upper and a lower electrode, a manner for applying a high frequency power is not limited thereto. For instance, other plasma apparatuses such as an inductively coupled plasma etching apparatus can be used. Further, other processes, e.g., ashing and CVD, are carried out without being limited to etching. Furthermore, even if a process is not the plasma processing, the process can be performed as long as the processing vessel is depressurized in the process. Moreover, although the He gas is used as a heat transfer gas, it is possible to use other gases such as Ar gas, a mixed gas containing He gas and Ar gas or the like. Besides, a substrate to be processed can be a flat panel display substrate or the like without being limited to a semiconductor wafer.

What is claimed is:

1. A substrate mounting table for mounting a substrate in a substrate processing apparatus, comprising:
a mounting table main body;
an annular peripheral protrusion portion which is formed such that when the substrate is loaded on a reference surface at a substrate mounting side of the mounting table main body, it is in contact with a peripheral portion of the substrate and a sealed space filled with a heat transfer gas is formed below the substrate;
a plurality of first protrusions which are formed on the reference surface inward from the annular peripheral protrusion portion such that they are in contact with the substrate when the substrate is loaded on the substrate mounting table; and
a number of second protrusions which are provided independently of the first protrusions on the reference surface inward from the annular peripheral protrusion portion such that they are close to the substrate without contacting it when the substrate is loaded on the substrate mounting table.

2. The substrate mounting table of claim 1, wherein a distance between the second protrusions and the mounted substrate is smaller than or equal to about 5 μm.

3. The substrate mounting table of claim 1, wherein both a contact area between the first protrusions and the mounted substrate and a facing area of the second protrusions facing the mounted substrate are smaller than or equal to about 0.8 mm².

4. The substrate mounting table of claim 1, wherein the first and the second protrusions have cylindrical shapes.

5. The substrate mounting table of claim 4, wherein the first and the second protrusions have diameters smaller than or equal to about 1 mm.

6. The substrate mounting table of claim 1, wherein an area ratio of the total contact area between the first protrusions and the mounted substrate to an area of the reference surface inward from the annular peripheral protrusion portion is about 0.04%˜5%.

7. The substrate mounting table of claim 6, wherein the first protrusions are uniformly arranged on the reference surface inward from the annular peripheral protrusion portion.

8. The substrate mounting table of claim 1, wherein an area ratio of the total facing area of the second protrusions facing the mounted substrate to an area of the reference surface where the second protrusions are formed is greater than or equal to about 15%.

9. The substrate mounting table of claim 8, wherein the second protrusions are distributed on the reference surface inward from the annular peripheral protrusion portion depending on a temperature distribution of the mounted substrate.

10. The substrate mounting table of claim 1, wherein the annular peripheral protrusion portion and the first protrusions have a height of about 30 μm from the reference surface.

11. The substrate mounting table of claim 1, further comprising an inner annular protruded portion, provided on the reference surface inward from the annular peripheral protrusion portion, for dividing the sealed space into an inner portion and an outer portion by being contact with the substrate when the substrate is mounted on the substrate mounting table.

12. The substrate mounting table of claim 11, wherein the inner annular protruded portion has a double structure of a first inner annular protruded portion and a second inner annular protruded portion which installed close to each other.

13. The substrate mounting table of claim 12, wherein heat transfer gas inlet units for introducing a heat transfer gas are respectively disposed in an inner portion and an outer portion of the sealed space divided by the inner annular protruded portion, and
a heat transfer gas inlet unit for introducing a heat transfer gas is further provided in a gap formed between the first inner annular protruded portion and the second inner annular protruded portion.

14. The substrate mounting table of claim 11, wherein the inner annular protruded portion includes a first annular wall; a second annular wall; and an annular recess formed between the first and the second annular wall provided close to each other.

15. The substrate mounting table of claim 14, wherein heat, transfer gas inlet units for introducing a heat transfer gas are respectively disposed in the inner portion and the outer portion of the sealed space divided by the inner annular protruded portion, and
a heat transfer gas inlet unit for introducing a heat transfer gas is further provided in the annular recess.

16. The substrate mounting table of claim 11, wherein a plurality of intermediate annular protruded portions is concentrically provided between the inner annular protruded portion and the annular peripheral protrusion portion.

17. The substrate mounting table of claim 14, wherein a heat transfer gas inlet unit for introducing a heat transfer gas is disposed in the inner portion of the sealed space confined by the inner annular protruded portion, and
heat transfer gas inlet units for introducing a heat transfer gas are further provided in a number of gaps formed in a plurality of intermediate annular protruded portions concentrically provided.

18. The substrate mounting table of claim 1, wherein the mounting table main body has an electrostatic chuck for attracting and holding the substrate by using an electrostatic force.

19. A substrate processing apparatus comprising:
a processing vessel, for accommodating a substrate, to be depressurized;
a substrate mounting table which is provided in the processing vessel and has a configuration described in claim 1;
a processing mechanism for performing a process on the substrate in the processing vessel; and
a heat transfer gas supply mechanism for feeding a heat transfer gas into a sealed space formed between the substrate mounting table and the substrate.

20. The substrate processing apparatus of claim 19, further comprising a controller for controlling a pressure of the heat transfer gas which is supplied from the heat transfer gas supply mechanism.

21. A substrate temperature controlling method for controlling a temperature of a substrate by employing the substrate mounting table described in claim 1, wherein the temperature of the substrate is controlled by controlling a pressure of a heat transfer gas fed into a sealed space formed between the substrate mounting table and the substrate.

22. A substrate temperature controlling method for controlling a temperature of a substrate by employing the substrate mounting table described in claim 11, wherein heat transfer gas inlet units for introducing a heat transfer gas are respectively disposed in the inner portion and the outer portion of the sealed space divided by the inner annular protruded portion, and pressures of the inner portion and the outer portion of the sealed space are independently controlled, thereby controlling the temperature of the substrate.

23. The substrate temperature controlling method of claim 22, wherein the inner annular protruded portion has a double structure of a first inner annular protruded portion and a second inner annular protruded portion installed close to each other, and
a heat transfer gas inlet unit for introducing a heat transfer gas is further provided in a gap formed between the first inner annular protruded portion and the second inner annular protruded portion such that a pressure in the gap is controlled to be lower than those in the inner portion and the outer portion of the sealed space.

24. The substrate temperature controlling method of claim 22, wherein the inner annular protruded portion includes a first annular wall; a second annular wall; and an annular recess formed between the first and the second annular wall provided close to each other, and
a heat transfer gas inlet unit for introducing a heat transfer gas is further provided in the annular recess such that a pressure in the recess is controlled to be lower than those in the inner portion and the outer portion of the sealed space.

25. A substrate temperature controlling method for controlling a temperature of a substrate by employing the substrate mounting table described in claim 11, wherein a heat transfer gas inlet unit for introducing a heat transfer gas is disposed in the inner portion of the sealed space confined by the inner annular protruded portion to thereby control a pressure in the inner portion of the sealed space, and
a plurality of intermediate annular protruded portions is concentrically provided between the inner annular protruded portion and the annular peripheral protrusion portion, and heat transfer gas inlet units for introducing a heat transfer gas are further provided in a number of gaps formed in the plurality of intermediate annular protruded portions such that pressures in a number of gaps is independently controlled to thereby control the temperature of the substrate.

26. A substrate processing apparatus comprising:
a processing vessel, for accommodating a substrate, to be depressurized;
a substrate mounting table, provided in the processing vessel, for mounting the substrate thereon;
a processing mechanism for performing a process on the substrate in the processing vessel;
a heat transfer gas supply mechanism for feeding a heat transfer gas into a sealed space formed between the substrate mounting table and the substrate; and
a controller for controlling the substrate mounting table to execute the substrate temperature controlling method described in claim 21.

27. A control program executed on a computer for controlling the substrate mounting table to perform the substrate temperature controlling method described in claim 21.

28. A computer storage medium for storing a control program executed on a computer for controlling the substrate mounting table to perform the substrate temperature controlling method described in claim 21.
